(19) United States
(12) Patent Application Publication
(10) Pub. No.: US 2013/0039513 A1
(43) Pub. Date: Feb. 14, 2013

(54) ELECTRONIC DEVICE AND METHOD FOR ADJUSTING VOLUME

(71) Applicant: QIANG YOU, Shenzhen City (CN)

(72) Inventor: QIANG YOU, Shenzhen City (CN)

(73) Assignees: HON HAI PRECISION INDUSTRY CO., LTD., Tu-Cheng (TW); FU TAI HUA INDUSTRY (SHENZHEN) CO., LTD., ShenZhen City (CN)

(21) Appl. No.: 13/235,446

(22) Filed: Sep. 18, 2011

(30) Foreign Application Priority Data
Aug. 10, 2011 (CN) 201110228009.4

(51) Int. Cl. H03G 3/00

(52) U.S. Cl. 381/107

(57) ABSTRACT

The disclosure provides an electronic device and a method for adjusting volume adapted for the device. The electronic device defines at least two work modes. The method includes steps: determining whether one of the at least two work modes is selected; detecting a pulse frequency of a user in real time when one of the at least two work modes is selected; determining whether the pulse frequency is less than a reference value; and if the pulse frequency is less than the reference value, adjusting a volume according the selected work mode.

### BACKGROUND

1. Technical Field

The disclosure relates to electronic devices, and particularly, to an electronic device and a method for adjusting volume adapted for the electronic device.

2. Description of Related Art

Electronic devices, such as a MP3 player, often cannot automatically adjusts the volume according to the activity the user is performing.

Therefore, what is needed is an electronic device to overcome the described shortcoming.

### BRIEF DESCRIPTION OF THE DRAWINGS

FIG. 1 is a block diagram of an electronic device, in accordance with an exemplary embodiment.

FIG. 2 is a flowchart of a method for adjusting volume employed by the electronic device of FIG. 1.

### DETAILED DESCRIPTION

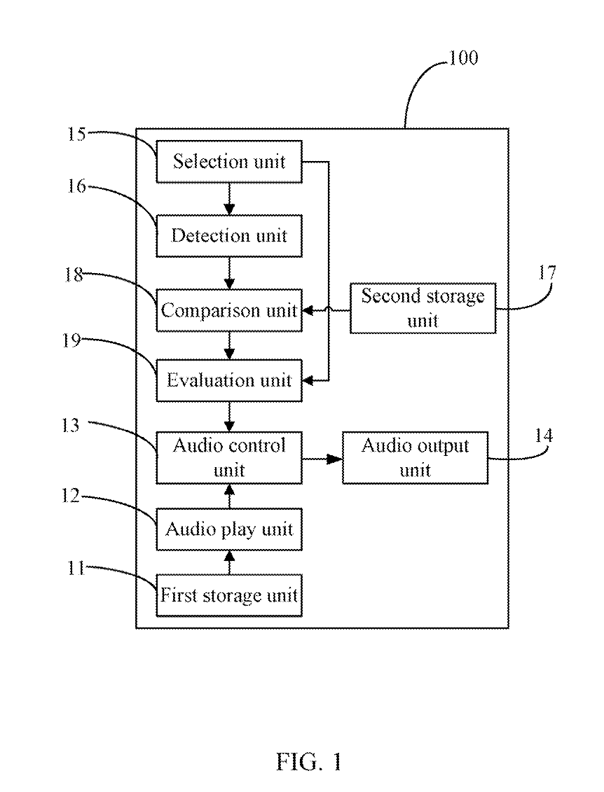

FIG. 1 is a block diagram of an electronic device, in accordance with an exemplary embodiment. The electronic device 100 includes a first storage unit 11, an audio play unit 12, an audio control unit 13, and an audio output unit 14. The first storage unit 11 is configured to store a number of audio files. The audio play unit 12 is configured to play the audio files in first storage unit 11. The audio output unit 14 is configured to output audio signals corresponding to each audio file. The audio output unit 14 can be a pair of earphones or a speaker. In the embodiment, the audio output unit 14 is earphones. The audio control unit 13 is configured to adjust a volume of the audio file played by the audio play unit 12.

The electronic device 100 further includes a selection unit 15, a detection unit 16, a second storage unit 17, a comparison unit 18, and an evaluation unit 19. The electronic device 100 defines at least two predetermined work modes. In the embodiment, the electronic device 100 defines two work modes: a sleep mode and a power mode. The electronic device 100 performs a predetermined function corresponding to one of the predetermined work modes.

The selection unit 15 is configured to select a work mode in response to user inputs and activate the work mode. The selection unit 15 can be a hard key, a soft key, or a combination of thereof. The detection unit 16 is configured to detect a pulse frequency of a user in real time. The detection unit 16 is a pulse sensor. In the embodiment, the pulse sensor 16 is set on the earphones 14. The second storage unit 17 is configured to store a reference value of the pulse frequency. In the embodiment, a pulse frequency of the user when he is sleeping is defined as the reference value. For example, the reference value is 65 times per minute.

The comparison unit 18 is configured to compare a current pulse frequency of the user with the reference value and generate a result signal when the current pulse frequency of the user is less than the reference value. The evaluation unit 19 is configured to determine that the selected work mode is the sleep mode or the power mode in response to the result signal. When the electronic device 100 is in the sleep mode, the evaluation unit 19 generates a first volume control signal. When the electronic device 100 is in the power mode, the evaluation unit 19 generates a second volume control signal.

The audio control unit 13 is respectively configured to adjust the output volume of the audio output unit 14 in response to the first or the second volume control signals. Concretely, the audio control unit 13 turns down the output volume of the audio output unit 14 in response to the first volume control signal and turns up the output volume of the audio output unit 14 in response to the second volume control signal.

Therefore, when the current pulse frequency of the user is less than the reference value and the current work mode of the electronic device 100 is the sleep mode, the audio control unit 13 turns down the output volume of the audio output unit 14, thus the user can have a good rest. When the current pulse frequency of the user is less than the reference value and the current work mode of the electronic device 100 is the power mode, the audio control unit 13 turns up the output volume of the audio output unit 14, to keep the user awake or from falling asleep.

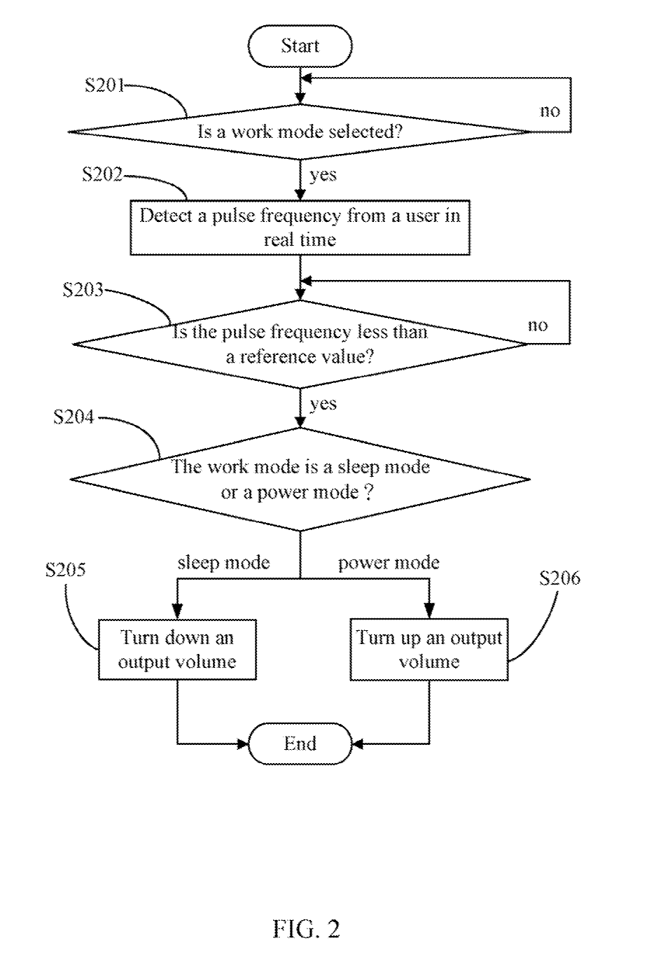

FIG. 2 is a flowchart of a method for adjusting volume employed by the electronic device of FIG. 1. In step S201, the electronic device 1 determines whether the predetermined work mode is selected by the selection unit 15. If yes, the procedure goes to step S202, otherwise, the procedure returns to step S201. In step S202, the detection unit 16 detects the pulse frequency of the user in real time. In step S203, the comparison unit 18 determines whether the pulse frequency is less than the reference value. If yes, in step S204, the evaluation unit 19 determines that the work mode is the sleep mode or the power mode. In step S205, when the current work mode of the electronic device 100 is the sleep mode, the audio control unit 13 turns down the output volume of the audio output unit 14. In step S206, when the current work mode of the electronic device 100 is the power mode, the audio control unit 13 turns up the output volume of the audio output unit 14.

Although the present disclosure has been specifically described on the basis of the exemplary embodiment thereof, the disclosure is not to be construed as being limited thereto. Various changes or modifications may be made to the embodiment without departing from the scope and spirit of the disclosure.

What is claimed is:

1. An electronic device defining at least two work modes, comprising:
a selection unit to select a work mode of the at least two work modes;
a detection unit to detect a pulse frequency of a user in real time;
a comparison unit to compare the pulse frequency with a reference value; and
an audio control unit to adjust a volume according to the selected work mode when the current pulse frequency is less than the reference value.

2. The electronic device as recited in claim 1, wherein a pulse frequency of the user when sleeping is defined as the reference value.

3. The electronic device as recited in claim 1, wherein the at least two work modes comprises a sleep mode and a power mode, the audio control unit turns down the volume in the sleep mode and turns up the volume in the power mode.

4. The electronic device as recited in claim 1, wherein the detection unit is a pulse sensor.

5. A method for adjusting volume adapted for an electronic device, the electronic device defining at least two work modes, the method comprising:
determining whether one of the at least two work modes is selected;
detecting a pulse frequency of a user in real time when one of the at least two work modes is selected;
determining whether the pulse frequency is less than a reference value; and
if the pulse frequency is less than the reference value, adjusting a volume according the selected work mode.

6. The method for adjusting volume as recited in claim 5, wherein a pulse frequency of the user when sleeping is defined as the reference value.

7. The method for adjusting volume as recited in claim 5, wherein the at least two work modes comprise a sleep mode and a power mode, the method further comprising:
turning down the volume in the sleep mode and turning up the volume in the power mode.
